(19) United States
(12) Patent Application Publication
(10) Pub. No.: US 2012/0234238 A1
(43) Pub. Date: Sep. 20, 2012

(54) INTEGRATED METROLOGY FOR WAFER SCREENING

(76) Inventors: Wei-Yung Hsu, San Jose, CA (US); Hua Chung, San Jose, CA (US); Ting-Ruei Shiu, Mountain View, CA (US); Jie Cui, Albany, CA (US)

(21) Appl. No.: 13/419,121

(22) Filed: Mar. 13, 2012

Related U.S. Application Data
(60) Provisional application No. 61/454,440, filed on Mar. 18, 2011.

(51) Int. Cl. C23C 16/52; G01N 3/00

(52) U.S. Cl. 118/712; 73/788

(57) ABSTRACT

Integrated wafer or substrate bow measurement modules are described. For example, a multi-chamber system includes a chamber housing a bow measurement module. In another example, a method of pre-screening a wafer includes inserting a wafer or a substrate into a multi-chamber system. A bow parameter of the wafer or the substrate is measured in a bow measurement module housed in a chamber of the multi-chamber system.

### CROSS-REFERENCE TO RELATED APPLICATIONS

This application claims the benefit of U.S. Provisional Application No. 61/454,440, filed Mar. 18, 2011, the entire contents of which are hereby incorporated by reference herein.

### BACKGROUND

1) Field

Embodiments of the present invention pertain to the field of metrology and, in particular, to integrated wafer or substrate bow measurement modules.

2) Description of Related Art

Group III-V materials are playing an ever increasing role in the semiconductor, e.g. power devices, and related, e.g. light-emitting diode (LED), industries. Often, group III-V materials are difficult to grow or deposit on foreign substrates (known as heteroepitaxy) without the formation of defects or cracks. For example, high quality surface preservation of select films, e.g. a gallium nitride film, is not straightforward in many applications using stacks of material layers fabricated sequentially. The inclusion of one or more buffer layers between a substrate and a device layer has been one approach. However, group III-V materials are often sensitive to process conditions and care must be taken to avoid such conditions at particular periods of the fabrication process. Avoiding interaction of a sensitive group III-V film with potential damaging conditions, however, is also not straightforward in many applications.

Another potential issue with fabricating group III-V materials may be due to the starting semiconductor substrate or wafer onto which the materials are formed. For example, not every semiconductor substrate or wafer, e.g. a sapphire substrate, is perfectly flat and/or free from stress. The growth quality of group III-V material layers, and other material layers for that matter, may be hampered if the semiconductor substrate or wafer is not perfectly flat and/or free from stress, particularly if such deviation is significant. Manifestations of deviations in substrates or wafers may include substrate or wafer bow or warp. Bow is the deviation of the center point of the median surface of a free, un-clamped wafer from the median surface to the reference plane. The reference plane is defined by three corners of equilateral triangle. Warp is the difference between the maximum and the minimum distances of the median surface of a free, un-clamped wafer from the reference plane defined above.

### SUMMARY

One or more embodiments of the present invention are directed to integrated wafer or substrate bow measurement modules.

In an embodiment, a multi-chamber system includes a chamber housing a bow measurement module.

In another embodiment, a method of pre-screening a wafer includes inserting a wafer or a substrate into a multi-chamber system. A bow parameter of the wafer or the substrate is measured in a bow measurement module housed in a chamber of the multi-chamber system.

### BRIEF DESCRIPTION OF THE DRAWINGS

FIG. 1A illustrates a portion of a loading station of a cluster tool integrated with a bow measurement module coupled with a wafer aligner or with a cassette carousel in the loading station, in accordance with an embodiment of the present invention.

FIG. 1B illustrates a portion of a transfer station of a cluster tool integrated with a bow measurement module, in accordance with an embodiment of the present invention.

FIG. 1C illustrates a portion of a transfer station of a cluster tool integrated with multiple bow measurement modules, in accordance with an embodiment of the present invention.

FIG. 2A illustrates a bowed wafer or substrate in a carrier at an elevated temperature.

FIG. 2B illustrates a bowed wafer or substrate with indications of measurements made from a bow measurement module, in accordance with an embodiment of the present invention.

FIG. 2C illustrates a schematic diagram of a portion of a bow measurement module suitable for performing a laser scan feedback bow measurement, in accordance with an embodiment of the present invention.

FIG. 2D illustrates a diameter scan of a bow measurement module, in accordance with an embodiment of the present invention.

FIG. 3A illustrates a cluster tool schematic, in accordance with an embodiment of the present invention.

FIG. 3B illustrates a light-emitting diode (LED) structure, in accordance with an embodiment of the present invention.

FIG. 4 is a schematic cross-sectional view of a MOCVD chamber, in accordance with an embodiment of the present invention.

FIG. 5 is a schematic cross-sectional view of a HVPE chamber, in accordance with an embodiment of the present invention.

FIG. 6 illustrates a block diagram of an exemplary computer system, in accordance with an embodiment of the present invention.

### DETAILED DESCRIPTION

Integrated wafer or substrate bow measurement modules are described. In the following description, numerous specific details are set forth, such as bow measurement module location and positioning and process chamber configurations, in order to provide a thorough understanding of embodiments of the present invention. It will be apparent to one skilled in the art that embodiments of the present invention may be practiced without these specific details. In other instances, well-known features, such as specific diode configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

Photoluminescent (PL) wavelength uniformity may be a critical specification for light-emitting diode (LED) epitaxial layer-on-wafer production. Wafer quality, especially wafer bow parameters, plays a particularly important role in achieving PL wavelength uniformity. This relationship may be linked to the impact of wafer bow on temperature uniformity during layer fabrication.

The incoming bow of a bare substrate or wafer, such as a sapphire substrate or wafer, typically correlates well with epitaxial layer quality and, hence, device quality of layers and devices formed on the wafer or substrate. For example, the greater the bow in a wafer, the fewer high performance LEDs that may often be formed on the wafer. This understanding has led to the implementation of specifications for wafer and substrate batches, often requiring testing of approximately 1 in 100 of such wafers or substrates. Problems may arise, however, even with the implemented “pre-screening” specification guidelines. For example, it is usually the case that not every wafer or substrate is measured for bow. Instead, usually only about 1% of a batch is sampled. Furthermore, the fabrication end of device manufacture, such as LED manufacture, may require tighter specification guidelines than available from the wafer or substrate supplier.

Accordingly, in one or more embodiments of the present invention, an integrated bow measurement module is integrated with an LED, or other group III-V device, epitaxial capability system. In one such embodiment, the bow measurement module is used to monitor wafer bow. Wafers that fall outside of a desired specification guideline are then removed before processing on the wafers is initiated. In this, way, in contrast to binning and testing already formed devices, overall yield may be increased by discarding non-conforming (i.e., too high a bow parameter) substrates or wafers before epitaxial formation thereon. In specific embodiments of the present invention, a bow measurement module is included in a multi-chamber tool such that wafer selection (often requiring wafer exposure) is performed in the same tool in which epitaxial layers are subsequently formed. Concepts included in at least some embodiments of the present invention include, but are not limited to: (a) light-emitting diodes (LEDs), (b) multi-quantum well (MQW) wavelength, (c) PL wavelength uniformity, (d) wafer bow measurements, and (e) integrated metrology.

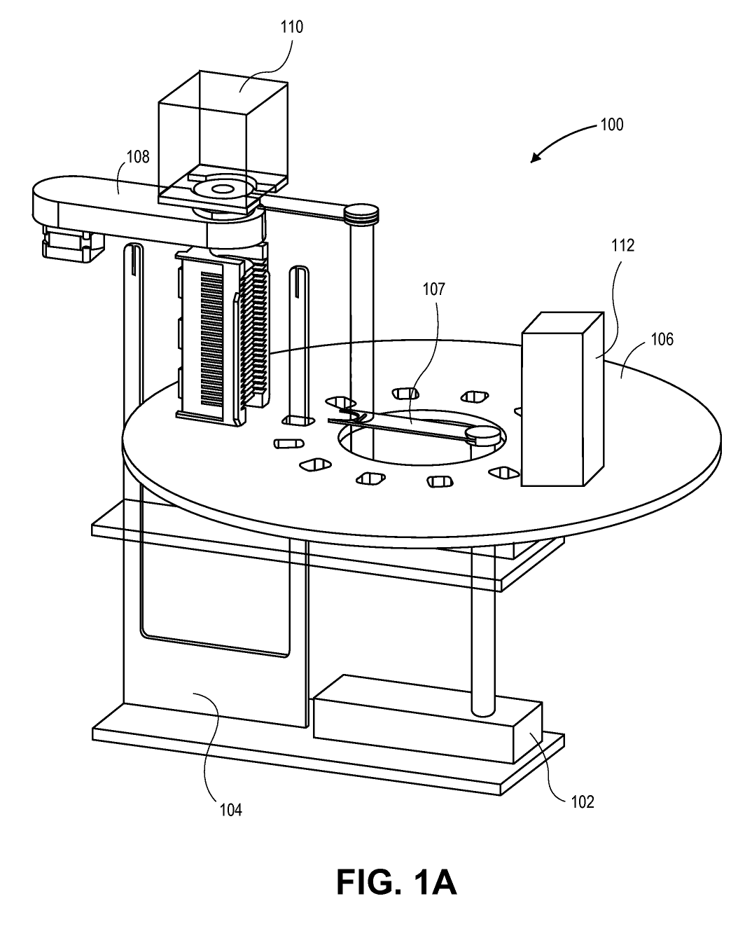

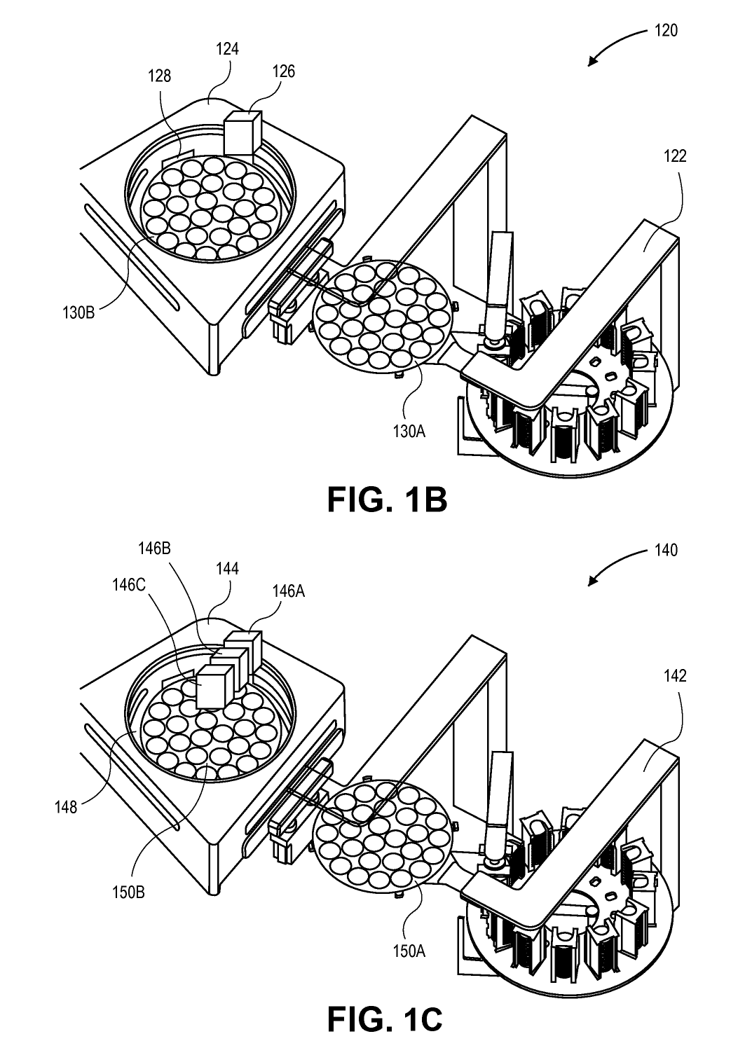

In an aspect of the present invention, a bow measurement module is incorporated into a multi-chamber tool. As a first example, FIG. 1A illustrates a portion of a loading station of a multi-chamber tool integrated with a bow measurement module coupled with a wafer aligner or with a cassette carousel in the loading station, in accordance with an embodiment of the present invention.

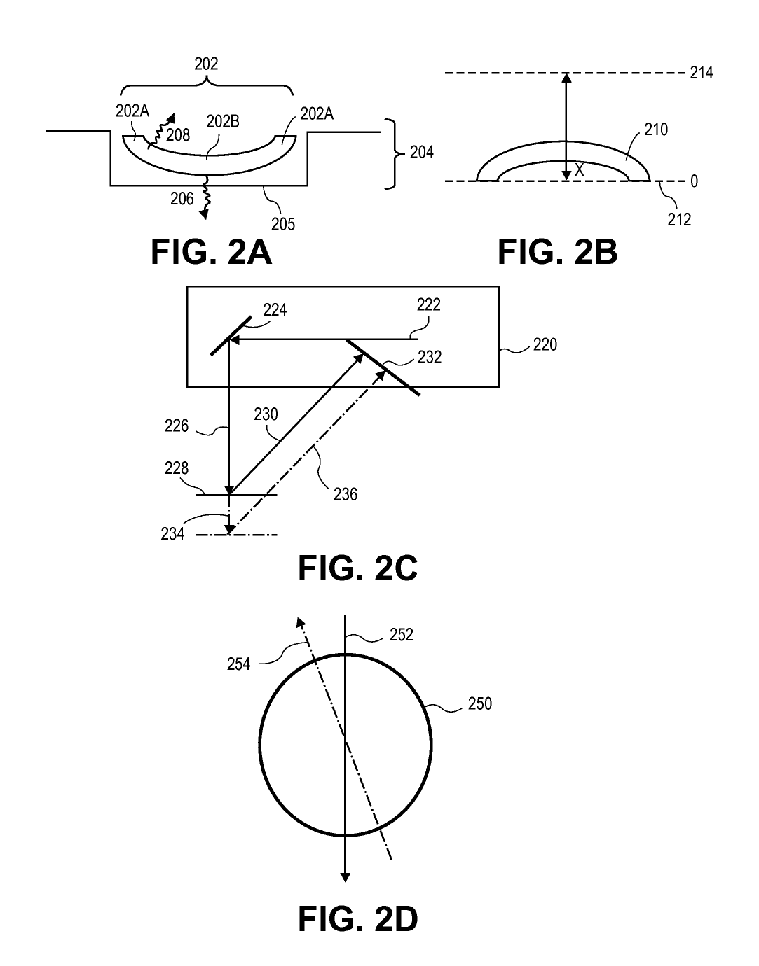

Referring to FIG. 1A, a portion 100 of a loading station of a multi-chamber tool includes a wafer transfer module 102, a wafer mapper 104, a cassette carousel 106 (with a wafer handler 107), and a wafer aligner 108. In an embodiment, a bow measurement module 110 is coupled with the wafer aligner 108. For example, the bow measurement module 110 may reside directly above the wafer aligner 108, as depicted in FIG. 1A. In such an embodiment, the bow of each wafer or substrate aligned in the wafer aligner 108 is available for measurement. In a particular embodiment, the bow measurement may be made by the bow measurement module 110 without interruption to the aligning process, i.e., the measurement may be made at the same time as the aligning is performed. Furthermore, in cases where the bow measurement is made by a scanning procedure (as described below in association with FIG. 2C), two bow measurements may be made for each wafer or substrate during the aligning process (as described below in association with FIG. 2D).

In another embodiment, referring again to FIG. 1A, a second bow measurement module 112 is coupled with the cassette carousel 106. For example, the second bow measurement module 112 may reside directly above the cassette carousel 106, as depicted in FIG. 1A. In such an embodiment, the bow of each wafer or substrate handled by the wafer handler 107 of the cassette carousel 106 is available for measurement. However, in a particular embodiment, the bow measurement is made by the second bow measurement module 112 upon interruption to the aligning process. It is noted that although both bow measurement modules 110 and 112 are depicted in FIG. 1A, which may be the case in one embodiment, only one of the bow measurement modules 110 and 112 may be need to be included, in accordance with other embodiments of the present invention. Following measurement in one or both of the bow measurement modules 110 and 112, a measured wafer or substrate that passes a specification guideline may subsequently be transferred into a wafer carrier.

As a second example, FIG. 1B illustrates a portion of a transfer station of a multi-chamber tool integrated with a bow measurement module, in accordance with an embodiment of the present invention.

Referring to FIG. 1B, a portion 120 of a transfer station of a multi-chamber tool includes a carrier transfer module 122 and a carrier receiving module 124. In an embodiment, a bow measurement module 126 is coupled with the carrier receiving module 124. For example, the bow measurement module 126 may reside directly above an opening 128 of the carrier receiving module 124, as depicted in FIG. 1B. In such an embodiment, the bow of each wafer or substrate at a given radius within a carrier 130A/B is available for measurement. In a particular embodiment, the bow measurement may be made by the bow measurement module 126 upon transfer of the carrier from position 130A to position 130B, the later position located within the carrier receiving module 124. However, it is to be understood that for substrates or wafers that fail the specification guidelines of the bow measurement, the carrier 130A/B is removed from the carrier receiving module 124 in order to remove such substrates or wafers. Such a process may be more time consuming or more laborious than the arrangements described above in association with FIG. 1A. Furthermore, in the arrangement of FIG. 1B, only those substrates or wafers placed at a particular radius of the carrier 130A/B are available for measurement.

Thus, as a third example, FIG. 1C illustrates a portion of a transfer station of a multi-chamber tool integrated with multiple bow measurement modules, in accordance with an embodiment of the present invention.

Referring to FIG. 1C, a portion 140 of a transfer station of a multi-chamber tool includes a carrier transfer module 142 and a carrier receiving module 144. In an embodiment, a series of bow measurement modules 146A, 146B, and 146C is coupled with the carrier receiving module 144. For example, the series of bow measurement modules 146A, 146B, and 146C may reside directly above an opening 148 of the carrier receiving module 144, as depicted in FIG. 1C. In such an embodiment, the bow of each wafer or substrate at a multiple of given radii (in this case, at three different radii) within a carrier 150A/B is available for measurement. In a particular embodiment, the bow measurement may be made by one or more of the series of bow measurement modules 146A, 146B, and 146C upon transfer of the carrier from position 150A to position 150B, the later position located within the carrier receiving module 144. However, it is to be understood that for substrates or wafers that fail the specification guidelines of the bow measurement, the carrier 150A/B is removed from the carrier receiving module 144 in order to remove such substrates or wafers. Such a process may be more time consuming or more laborious than the arrangements described above in association with FIG. 1A.

In an aspect of the present invention, a bow measurement module is used to perform a bow measurement on a wafer or a substrate by a laser scan feedback approach.

FIG. 2A illustrates a bowed wafer or substrate 202 in a carrier 204 at an elevated temperature. Demonstrating the detrimental effects of bowing in a substrate or wafer, outer portions 202A of bowed wafer or substrate 202 are farther away from the heated bottom portion 205 of carrier 204 than is central portion 202B of bowed wafer or substrate 202. A luminescence measurement made on bowed wafer or substrate 202 typically reveals shorter wavelengths 206 emitted from central portion 202B, indicating a hotter region. Meanwhile the same luminescence measurement typically reveals longer wavelengths 208 emitted from outer portions 202A, indicating cooler regions. Unfortunately, the difference in temperature, as indicated by wavelength of emission, often may only be tolerated for relatively small temperature differences. For example, a difference in distance from the heated bottom portion 205 of carrier 204 of merely 1-2 nanometers can lead to temperature differences of a degree Celsius. That is, the difference is usually 1-2 nanometers/degree Celsius. It may be desirable to achieve a tight uniformity (minimal bow) across bowed wafer or substrate 202 of as little as 5 nanometers to ensure a temperature processing difference of only approximately 2.5 degrees Celsius. It is noted that, in one embodiment, carrier 204 is a silicon carbide carrier or a graphite carrier.

FIG. 2B illustrates a bowed wafer or substrate 210 with indications of measurements made from a bow measurement module, in accordance with an embodiment of the present invention. For example, referring to FIG. 2B, a specification guideline for a bow measurement of bowed wafer or substrate 210 requires a centrally upward bowing. That is, relative to surface 212, set at reference measurement 0, and surface 214, the central portion of bowed wafer or substrate 210 is farther from surface 212 (closer to surface 214) than the outer portions of bowed wafer or substrate 210. The amount of bow is given by parameter “x,” the distance from surface 212, which is typically provided as a negative number.

In an exemplary embodiment, a specification guideline for a bow measurement of bowed wafer or substrate 210 requires the centrally upward bowing to be within a value x approximately in the range of 0 to −20 microns. In one embodiment, only centrally upward bowing is acceptable, while all wafers or substrates with centrally downward bowing (usually referred to with a positive value, x) are unacceptable. In a specific embodiment, the acceptable value x varies by diameter of substrate or wafer, e.g., 2 inch, 4 inch, 6 inch, etc. diameters. In an embodiment, the range of 0 to −20 microns is for a bow measurement temperature of approximately 25 degrees Celsius at approximately 1 atmosphere of pressure.

FIG. 2C illustrates a schematic diagram of a portion of a bow measurement module suitable for performing a laser scan feedback bow measurement, in accordance with an embodiment of the present invention.

Referring to FIG. 2C, a portion 220 of a bow measurement module includes a laser beam source capable of emitting a laser beam 222. A reflector 224, such as a mirror, directs a reflected beam 226 to a surface 228 of a wafer or substrate. The wafer or substrate reflects a beam 230 to a detector 232. The detector 232 provides information as to the location at which beam 230 impinges on detector 232. If the height of the surface 228 is changed, as depicted by the dashed line below surface 228, reflected beam 226 is extended by an amount 234. The new position of the surface 228 directs a reflected beam 226 to a surface 228 of a wafer or substrate. The wafer or substrate reflects a beam 236 to the detector 232. The detector 232 provides information as to the location at which beam 236 impinges on detector 232. Thus, based on the location of the beam impinging on detector 232, a determination may be made as to the height of the surface of the wafer or substrate being measured.

FIG. 2D illustrates a diameter scan of a bow measurement module, in accordance with an embodiment of the present invention. When the laser scan described in association with FIG. 2C is applied along a diameter pathway 252 across a wafer or substrate 250, information may be collected as to the changing height of the wafer or substrate undergoing the scan. For example, in one embodiment, a laser scan applied along the diameter pathway 252 is used to reveal if the central portion of the substrate or wafer 250 is indeed the highest pint (centrally bowed upward) and the extent to which the bow occurs. Referring again to FIG. 2D, if the diameter scan is performed at a time and in a location wherein the substrate or wafer 250 is moved through a bow measurement module and then brought back through the same module, a second scan 254 may be made.

In a particular example, a bow measurement module is coupled with a wafer aligner. A wafer or substrate is transported through the bow measurement module along a first scan 252 en route to the aligner. The wafer or substrate is then aligned, altering the radial position typically at least slightly. Then, wafer or substrate is transported back through the bow measurement module along a slightly modified second scan 254 since it has been rotated slightly.

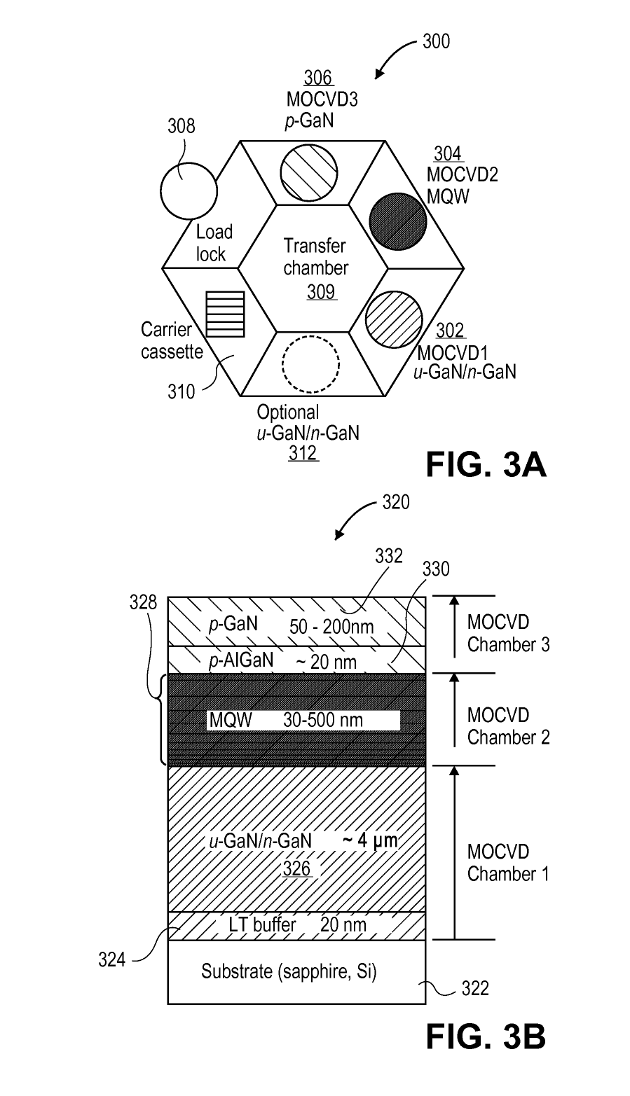

In an aspect of the present invention, a bow measurement module is incorporated into a cluster tool. FIG. 3A illustrates a cluster tool schematic, in accordance with an embodiment of the present invention.

Referring to FIG. 3A, a cluster tool 300 includes an un-doped and/or n-type gallium nitride MOCVD reaction chamber 302 (MOCVD1: u-GaN/n-GaN), a multiple quantum well (MQW) MOCVD reaction chamber 304 (MOCVD2: MQW), and a p-type gallium nitride MOCVD reaction chamber 306 (MOCVD3: p-GaN). The cluster tool 300 may also include a load lock 308, a transfer chamber 309, a carrier cassette chamber 310, and an optional additional un-doped and/or n-type gallium nitride MOCVD reaction chamber 312 for high volume applications, all of which are depicted in FIG. 3A. In accordance with an embodiment of the present invention, one or more wafer bow measurement modules is included in one or more of the load lock 308, the transfer chamber 309, or the carrier cassette chamber 310 of cluster tool 300.

In an aspect of the present invention, a measured wafer or substrate that passes a specification guideline in a bow measurement module is used for subsequent fabrication of a device such as a power device or a LED. As an example, FIG. 3B illustrates a light-emitting diode (LED) structure, in accordance with an embodiment of the present invention.

Referring to FIG. 3B, an LED structure 320 includes a stack of various material layers, many of which include materials. For example, the LED structure 320 includes a silicon or sapphire substrate 322 (Substrate: sapphire, Si), a 20 nanometer thick buffer layer 324 (LT buffer), and an approximately 4 microns thick un-doped/n-type gallium nitride combination layer 326 (u-GaN/n-GaN). The buffer layer 324 may be a gallium nitride layer formed at relatively low processing temperatures. The buffer layer 324 and the un-doped/n-type gallium nitride combination layer 326 are formed in un-doped and/or n-type gallium nitride MOCVD reaction chamber 302 of cluster tool 300. The LED structure 320 also includes an MQW structure 328 with a thickness in the range of 30-500 nanometers. The MQW structure 328 is formed in MQW MOCVD reaction chamber 304 of cluster tool 300. The LED structure 320 also includes an approximately 20 nanometers thick p-type gallium aluminum nitride layer 330 (p-AlGaN) and a p-type gallium nitride layer 332 with a thickness in the range of 50-200 nanometers (p-GaN). The p-type gallium aluminum nitride layer 330 and the p-type gallium nitride layer 332 are formed in p-type gallium nitride MOCVD reaction chamber 306 of cluster tool 300.

Exemplary embodiments of tool platforms suitable for housing an integrated bow measurement module include an Opus™ AdvantEdge™ system or a Centura™ system, both commercially available from Applied Materials, Inc. of Santa Clara, Calif. Embodiments of the present invention further include another integrated metrology (IM) chamber as a component of the multi-chambered processing platform. The IM chamber may provide control signals to allow adaptive control of integrated deposition processes. The IM chamber may include a metrology apparatus suitable to measure various film properties, such as thickness, roughness, composition, and may further be capable of characterizing grating parameters such as critical dimensions (CD), sidewall angle (SWA), feature height (HT) under vacuum in an automated manner. Examples include, but are not limited to, optical techniques like reflectometry and scatterometry. In particularly advantageous embodiments, in-vacuo optical CD (OCD) techniques are employed where the attributes of a grating formed in a starting material are monitored as the sputter and/or epitaxial growth proceeds. In other embodiments, metrology operations are performed in a process chamber, e.g., in-situ in the process chamber, rather than in a separate IM chamber.

A multi-chambered processing platform, such as cluster tool 300 may further include a substrate aligner chamber, as well as load lock chambers holding cassettes, coupled to a transfer chamber including a robotic handler. In one embodiment of the present invention, adaptive control of the multi-chambered processing platform 300 is provided by a controller. The controller may be one of any form of general-purpose data processing system that can be used in an industrial setting for controlling the various subprocessors and subcontrollers. Generally, the controller includes a central processing unit (CPU) in communication with a memory and an input/output (I/O) circuitry, among other common components. As an example, the controller may perform or otherwise initiate one or more of the operations of any of the methods/processes described herein. Any computer program code that performs and/or initiates such operations may be embodied as a computer program product. Each computer program product described herein may be carried by a medium readable by a computer (e.g., a floppy disc, a compact disc, a DVD, a hard drive, a random access memory, etc.).

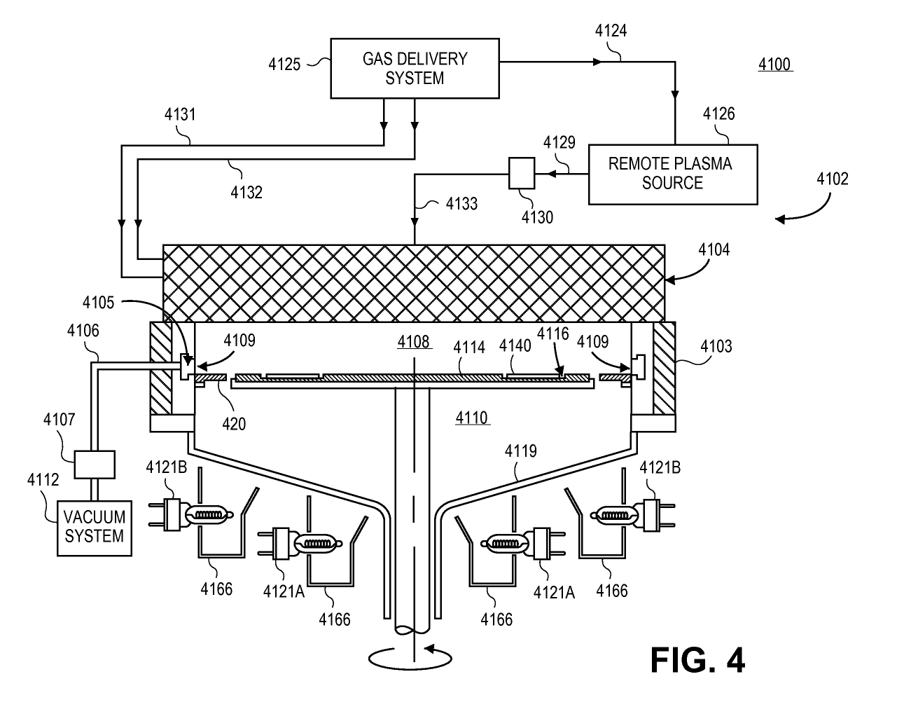

An example of an MOCVD deposition chamber which may be suitable for use as one or more of MOCVD chambers 302, 304, or 306, described above, is illustrated and described with respect to FIG. 4. FIG. 4 is a schematic cross-sectional view of an MOCVD chamber according to an embodiment of the invention.

The apparatus 4100 shown in FIG. 4 includes a chamber 4102, a gas delivery system 4125, a remote plasma source 4126, and a vacuum system 4112. The chamber 4102 includes a chamber body 4103 that encloses a processing volume 4108. A showerhead assembly 4104 is disposed at one end of the processing volume 4108, and a substrate carrier 4114 is disposed at the other end of the processing volume 4108. A lower dome 4119 is disposed at one end of a lower volume 4110, and the substrate carrier 4114 is disposed at the other end of the lower volume 4110. The substrate carrier 4114 is shown in process position, but may be moved to a lower position where, for example, the substrates 4140 may be loaded or unloaded. An exhaust ring 4120 may be disposed around the periphery of the substrate carrier 4114 to help prevent deposition from occurring in the lower volume 4110 and also help direct exhaust gases from the chamber 4102 to exhaust ports 4109. The lower dome 4119 may be made of transparent material, such as high-purity quartz, to allow light to pass through for radiant heating of the substrates 4140. The radiant heating may be provided by a plurality of inner lamps 4121A and outer lamps 4121B disposed below the lower dome 4119, and reflectors 4166 may be used to help control chamber 4102 exposure to the radiant energy provided by inner and outer lamps 4121A, 4121B. Additional rings of lamps may also be used for finer temperature control of the substrate 4140.

The substrate carrier 4114 may include one or more recesses 4116 within which one or more substrates 4140 may be disposed during processing. The substrate carrier 4114 may carry six or more substrates 4140. In one embodiment, the substrate carrier 4114 carries eight substrates 4140. It is to be understood that more or less substrates 4140 may be carried on the substrate carrier 4114. Typical substrates 4140 may include sapphire, silicon carbide (SiC), silicon, or gallium nitride (GaN). It is to be understood that other types of substrates 4140, such as glass substrates 4140, may be processed. Substrate 4140 size may range from 50 mm-100 mm in diameter or larger. The substrate carrier 4114 size may range from 200 mm-750 mm. The substrate carrier 4114 may be formed from a variety of materials, including SiC or SiC-coated graphite. It is to be understood that substrates 4140 of other sizes may be processed within the chamber 4102 and according to the processes described herein. The showerhead assembly 4104 may allow for more uniform deposition across a greater number of substrates 4140 and/or larger substrates 4140 than in traditional MOCVD chambers, thereby increasing throughput and reducing processing cost per substrate 4140.

The substrate carrier 4114 may rotate about an axis during processing. In one embodiment, the substrate carrier 4114 may be rotated at about 2 RPM to about 100 RPM. In another embodiment, the substrate carrier 4114 may be rotated at about 30 RPM. Rotating the substrate carrier 4114 aids in providing uniform heating of the substrates 4140 and uniform exposure of the processing gases to each substrate 4140.

The plurality of inner and outer lamps 4121A, 4121B may be arranged in concentric circles or zones (not shown), and each lamp zone may be separately powered. In one embodiment, one or more temperature sensors, such as pyrometers (not shown), may be disposed within the showerhead assembly 4104 to measure substrate 4140 and substrate carrier 4114 temperatures, and the temperature data may be sent to a controller (not shown) which can adjust power to separate lamp zones to maintain a predetermined temperature profile across the substrate carrier 4114. In another embodiment, the power to separate lamp zones may be adjusted to compensate for precursor flow or precursor concentration non-uniformity. For example, if the precursor concentration is lower in a substrate carrier 4114 region near an outer lamp zone, the power to the outer lamp zone may be adjusted to help compensate for the precursor depletion in this region.

The inner and outer lamps 4121A, 4121B may heat the substrates 4140 to a temperature of about 400 degrees Celsius to about 1200 degrees Celsius. It is to be understood that the invention is not restricted to the use of arrays of inner and outer lamps 4121A, 4121B. Any suitable heating source may be utilized to ensure that the proper temperature is adequately applied to the chamber 4102 and substrates 4140 therein. For example, in another embodiment, the heating source may include resistive heating elements (not shown) which are in thermal contact with the substrate carrier 4114.

A gas delivery system 4125 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 4102. Different gases, such as precursor gases, carrier gases, purge gases, cleaning/etching gases or others may be supplied from the gas delivery system 4125 to separate supply lines 4131, 4132, and 4133 to the showerhead assembly 4104. The supply lines 4131, 4132, and 4133 may include shut-off valves and mass flow controllers or other types of controllers to monitor and regulate or shut off the flow of gas in each line.

A conduit 4129 may receive cleaning/etching gases from a remote plasma source 4126. The remote plasma source 4126 may receive gases from the gas delivery system 4125 via supply line 4124, and a valve 4130 may be disposed between the showerhead assembly 4104 and remote plasma source 4126. The valve 4130 may be opened to allow a cleaning and/or etching gas or plasma to flow into the showerhead assembly 4104 via supply line 4133 which may be adapted to function as a conduit for a plasma. In another embodiment, apparatus 4100 may not include remote plasma source 4126 and cleaning/etching gases may be delivered from gas delivery system 4125 for non-plasma cleaning and/or etching using alternate supply line configurations to shower head assembly 4104.

The remote plasma source 4126 may be a radio frequency or microwave plasma source adapted for chamber 4102 cleaning and/or substrate 4140 etching. Cleaning and/or etching gas may be supplied to the remote plasma source 4126 via supply line 4124 to produce plasma species which may be sent via conduit 4129 and supply line 4133 for dispersion through showerhead assembly 4104 into chamber 4102. Gases for a cleaning application may include fluorine, chlorine or other reactive elements.

In another embodiment, the gas delivery system 4125 and remote plasma source 4126 may be suitably adapted so that precursor gases may be supplied to the remote plasma source 4126 to produce plasma species which may be sent through showerhead assembly 4104 to deposit CVD layers, such as group films, for example, on substrates 4140. In general, a plasma, which is a state of matter, is created by the delivery of electrical energy or electromagnetic waves (e.g., radio frequency waves, microwaves) to a process gas (e.g., precursor gases) to cause it to at least partially breakdown to form plasma species, such as ions, electrons and neutral particles (e.g., radicals). In one example, a plasma is created in an internal region of the plasma source 4126 by the delivery electromagnetic energy at frequencies less than about 100 gigahertz (GHz). In another example, the plasma source 4126 is configured to deliver electromagnetic energy at a frequency between about 0.4 kilohertz (kHz) and about 200 megahertz (MHz), such as a frequency of about 162 megahertz (MHz), at a power level less than about 4 kilowatts (kW). It is believed that the formed plasma enhances the formation and activity of the precursor gas(es) so that the activated gases, which reach the surface of the substrate(s) during the deposition process can rapidly react to form a layer that has improved physical and electrical properties.

A purge gas (e.g., nitrogen) may be delivered into the chamber 4102 from the showerhead assembly 4104 and/or from inlet ports or tubes (not shown) disposed below the substrate carrier 4114 and near the bottom of the chamber body 4103. The purge gas enters the lower volume 4110 of the chamber 4102 and flows upwards past the substrate carrier 4114 and exhaust ring 4120 and into multiple exhaust ports 4109 which are disposed around an annular exhaust channel 4105. An exhaust conduit 4106 connects the annular exhaust channel 4105 to a vacuum system 4112 which includes a vacuum pump (not shown). The chamber 4102 pressure may be controlled using a valve system 4107 which controls the rate at which the exhaust gases are drawn from the annular exhaust channel 4105.

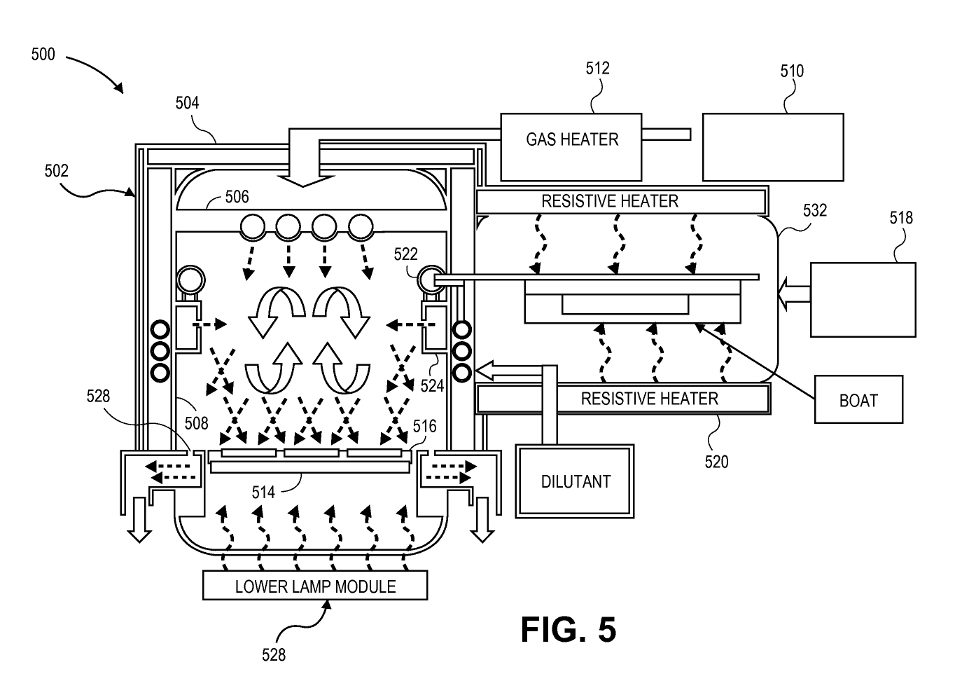

It is to be understood that any one or more chambers 302, 304, 306, or 312 of cluster tool 300 may be substituted with a hydride vapor phase epitaxy (HVPE) chamber. An example of a HVPE deposition chamber which may be suitable for such use is illustrated and described with respect to FIG. 5. FIG. 5 is a schematic cross-sectional view of a HVPE chamber 500, in accordance with an embodiment of the present invention.

The apparatus 500 includes a chamber 502 enclosed by a lid 504. Processing gas from a first gas source 510 is delivered to the chamber 502 through a gas distribution showerhead 506. In one embodiment, the gas source 510 includes a nitrogen containing compound. In another embodiment, the gas source 510 includes ammonia. In one embodiment, an inert gas such as helium or diatomic nitrogen is introduced as well either through the gas distribution showerhead 506 or through the walls 508 of the chamber 502. An energy source 512 may be disposed between the gas source 510 and the gas distribution showerhead 506. In one embodiment, the energy source 512 includes a heater. The energy source 512 may break up the gas from the gas source 510, such as ammonia, so that the nitrogen from the nitrogen containing gas is more reactive.

To react with the gas from the first source 510, precursor material may be delivered from one or more second sources 518. The precursor may be delivered to the chamber 502 by flowing a reactive gas over and/or through the precursor in the precursor source 518. In one embodiment, the reactive gas includes a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 532 and be heated with the resistive heater 520. By increasing the residence time that the chlorine containing gas is snaked through the chamber 532, the temperature of the chlorine containing gas may be controlled. By increasing the temperature of the chlorine containing gas, the chlorine may react with the precursor faster. In other words, the temperature is a catalyst to the reaction between the chlorine and the precursor.

In order to increase the reactivity of the precursor, the precursor may be heated by a resistive heater 520 within the second chamber 532 in a boat. The chloride reaction product may then be delivered to the chamber 502. The reactive chloride product first enters a tube 522 where it evenly distributes within the tube 522. The tube 522 is connected to another tube 524. The chloride reaction product enters the second tube 524 after it has been evenly distributed within the first tube 522. The chloride reaction product then enters into the chamber 502 where it mixes with the nitrogen containing gas to form a nitride layer on a substrate 516 that is disposed on a susceptor 514. In one embodiment, the susceptor 514 includes silicon carbide. The nitride layer may include n-type gallium nitride for example. The other reaction products, such as nitrogen and chlorine, are exhausted through an exhaust 526.

LEDs and related devices may be fabricated from layers of, e.g., group III-V films, especially group III-nitride films. Some embodiments of the present invention relate to forming gallium nitride (GaN) layers in a dedicated chamber of a fabrication tool, such as in a dedicated MOCVD chamber. In some embodiments of the present invention, GaN is a binary GaN film, but in other embodiments, GaN is a ternary film (e.g., InGaN, AlGaN) or is a quaternary film (e.g., InAlGaN). In at least some embodiments, the group III-nitride material layers are formed epitaxially. They may be formed directly on a substrate or on a buffers layer disposed on a substrate.

It is to be understood that embodiments of the present invention are not limited to formation of layers on the select substrates described above. Other embodiments may include the use of any suitable non-patterned or patterned single crystalline substrates upon epitaxial layers may be formed. The substrate may be one such as, but not limited to, a sapphire (Al₂O₃) substrate, a silicon (Si) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, and a lithium aluminum oxide (LiAlO₂) substrate. Any well know method, such as masking and etching may be utilized to form features, such as posts, from a planar substrate to create a patterned substrate. In a specific embodiment, however, a patterned sapphire substrate (PSS) is used with a (0001) orientation. Patterned sapphire substrates may be ideal for use in the manufacturing of LEDs because they increase the light extraction efficiency which is extremely useful in the fabrication of a new generation of solid state lighting devices. Substrate selection criteria may include lattice matching to mitigate defect formation and coefficient of thermal expansion (CTE) matching to mitigate thermal stresses.

Embodiments of the present invention may be provided as a computer program product, or software, that may include a machine-readable medium having stored thereon instructions, which may be used to program a computer system (or other electronic devices) to perform a process according to embodiments of the present invention. In one embodiment, the computer system is coupled with an apparatus described in association with FIGS. 1A, 1B, 1C, 3A, 4, or 5. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

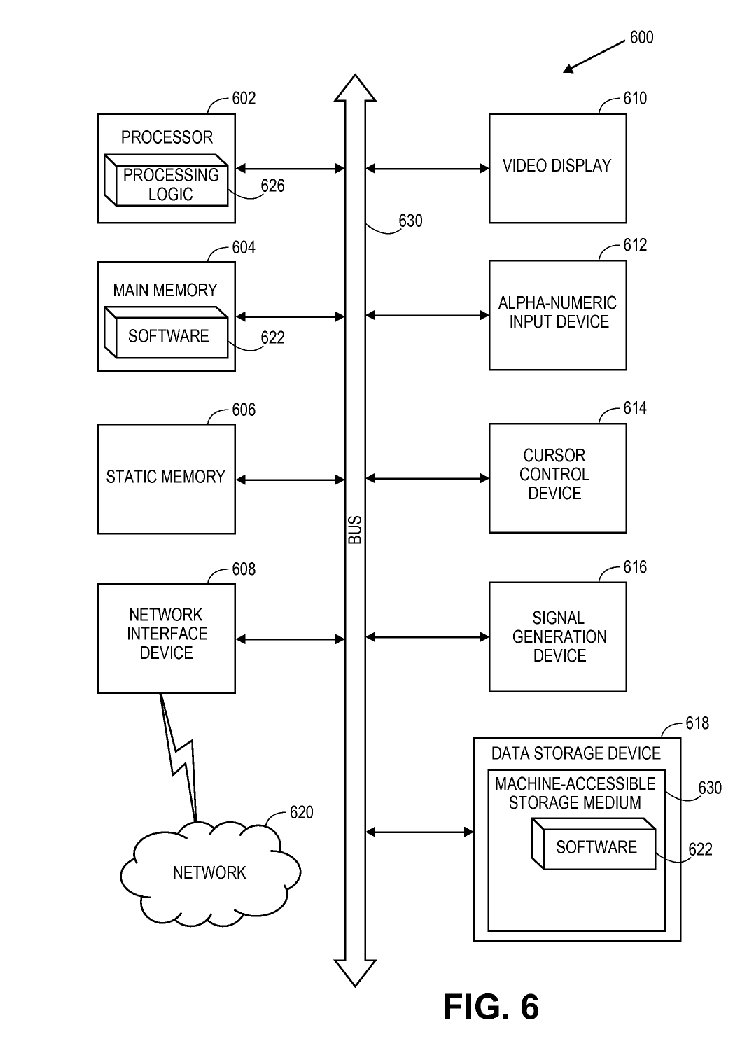

FIG. 6 illustrates a diagrammatic representation of a machine in the exemplary form of a computer system 600 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the operations described herein.

The computer system 600 may further include a network interface device 608. The computer system 600 also may include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium (or more specifically a computer-readable storage medium) 631 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

Thus, integrated wafer or substrate bow measurement modules have been disclosed. In an embodiment, a multi-chamber system includes a chamber housing a bow measurement module. In an embodiment, a method of pre-screening a wafer or a substrate includes inserting a wafer or a substrate into a multi-chamber system. A bow parameter of the wafer or the substrate is then measured in a bow measurement module housed in a chamber of the multi-chamber system.

What is claimed is:

1. A multi-chamber system, comprising:
a chamber; and
a bow measurement module housed in the chamber.

2. The multi-chamber system of claim 1, wherein the chamber housing the bow measurement module is a loading station.

3. The multi-chamber system of claim 2, wherein the bow measurement module is coupled with a wafer aligner of the loading station.

4. The multi-chamber system of claim 2, wherein the bow measurement module is coupled with a cassette carousel of the loading station.

5. The multi-chamber system of claim 1, wherein the chamber housing the bow measurement module is a transfer station.

6. The multi-chamber system of claim 5, wherein the transfer station further comprises one or more additional bow measurement modules.

7. The multi-chamber system of claim 1, further comprising:
an MOCVD chamber.

8. The multi-chamber system of claim 7, wherein the MOCVD chamber is configured for forming group III-V material layers.

9. The multi-chamber system of claim 1, further comprising:
an HVPE chamber.

10. The multi-chamber system of claim 9, wherein the HVPE chamber is configured for forming group III-V material layers.

11. A method of pre-screening a wafer, the method comprising:
inserting a wafer or a substrate into a multi-chamber system; and
measuring a bow parameter of the wafer or the substrate in a bow measurement module housed in a chamber of the multi-chamber system.

12. The method of claim 11, wherein the chamber housing the bow measurement module is a loading station.

13. The method of claim 12, wherein the bow measurement module is coupled with a wafer aligner of the loading station.

14. The method of claim 12, wherein the bow measurement module is coupled with a cassette carousel of the loading station.

15. The method of claim 11, wherein the chamber housing the bow measurement module is a transfer station.

16. The method of claim 15, wherein the transfer station further comprises one or more additional bow measurement modules.

17. The method of claim 11, further comprising:
if the measured bow parameter of the wafer is acceptable, transferring the wafer or the substrate to an MOCVD chamber.

18. The method of claim 17, further comprising:
forming, in the MOCVD chamber, a group III-V material layer on the wafer or the substrate.

19. The method of claim 11, further comprising:
if the measured bow parameter of the wafer is acceptable, transferring the wafer or the substrate to an HVPE chamber.

20. The method of claim 19, further comprising:
forming, in the HVPE chamber, a group III-V material layer on the wafer or the substrate.
